(19) United States
(12) Patent Application Publication
(10) Pub. No.: US 2021/0293959 A1
(43) Pub. Date: Sep. 23, 2021

(54) LIDAR FOR MEASURING DISTANCE USING SELF-HETERODYNE DETECTION

(71) Applicant: KOREA ADVANCED INSTITUTE OF SCIENCE AND TECHNOLOGY, Daejeon (KR)

(72) Inventors: Hyo-Hoon PARK, Daejeon (KR); Hyeonho YOON, Daejeon (KR); Nam-Hyun KWON, Daejeon (KR); Kyeongjin HAN, Daejeon (KR)

(21) Appl. No.: 16/830,869

(22) Filed: Mar. 26, 2020

(30) Foreign Application Priority Data
Mar. 20, 2020 (KR) 10-2020-0034129

(51) Int. Cl. G01S 17/26; G01S 7/487; G01S 7/481

(52) U.S. Cl. CPC G01S 17/26; G01S 7/4814; G01S 7/487

(57) ABSTRACT

A LiDAR device is disclosed that measures a distance based on self-heterodyne detection using coherence. According to an embodiment, the LiDAR device includes a light generator that generates a coherent transmission light source having a first frequency at a specific interval and delivers a time when frequency modulation into the first frequency is performed to a distance measurement circuit, an optical transmitter that delivers the transmission light source, delivered from the light generator, to an optical heterodyne detector and radiates the transmission light source to an object of the free space, an optical receiver that receives a reception light source where the transmission light source is reflected from the object, the optical heterodyne detector that outputs an electrical signal of a beat frequency based on the transmission light source delivered from the light generator and the reception light source delivered from the optical receiver, and the distance measurement circuit that measures a distance to the object based on the electrical signal of the beat frequency delivered from the optical heterodyne detector and the frequency modulation time delivered from the light generator.

### CROSS-REFERENCE TO RELATED APPLICATIONS

A claim for priority under 35 U.S.C. § 119 is made to Korean Patent Application No, 10-2020-0034129 filed on 20 Mar. 2020, in the Korean Intellectual Property Office, the entire contents of which are hereby incorporated by reference.

### BACKGROUND

Embodiments of the inventive concept described herein relate to light detection and ranging (LiDAR) device for measuring a distance of an object on a space, and more particularly, relate to technologies for a method for measuring a distance based on self-heterodyne detection using coherence and for a LiDAR device applying the same.

Miniaturized. LiDAR technology for accurately and quickly detecting locations or shapes of objects in a remote place has been developed. A solid state LiDAR, which removes beam steering of an existing mechanical rotary part using an optical phased array using optical interference, facilitates small size and low power and is advantageous to mass production by applying high-integration silicon semiconductor integration technology.

However, because optical loss is large in an optical phased array, it is difficult for the solid state. LiDAR including the silicon-based optical phased array to generate an optical output of 10 mW or more from the optical phased array using a semiconductor laser light source. As the distance L from the object is long, because energy of light where a radiation beam is reflected and/or scattered from the object and is received is inversely proportional to L² to be reduced, it is difficult to measure a distance of some meters or more using a power of 10 mW using a single photon detector. For example, because a method for measuring a time of flight (ToF) used for distance measurement in a conventional LiDAR system disclosed in Korean Patent No. 10-1802243 uses direct detection where a photodetector (PD) directly measures an optical power of reflected light, a measurable distance is short.

Another conventional measurement method using a frequency modulation continuous wave (FMCW) disclosed in Korean Patent No. 10-1877388 is to measure a distance using a beating frequency by interference of reflected light and reference light. At this time, an optical power of the beating frequency is amplified by a power of the reference light according to a beating effect. Thus, when the power of the reference light is increased, the receive sensitivity of the reflected light may be greatly increased. It is possible to measure a distance of 100 m or more of a few mW using a current technology.

However, because such an FMCW scheme is very sensitive to a lasing frequency, it requires a wavelength variable laser which facilitates a stable, continuous frequency change in a very small range (1/100,000 or less) of a GHz level at a carrier frequency of 200 THz. Thus, it is difficult to manufacture an economical, efficient micro-LiDAR by applying a wavelength variable laser which linearly and minutely varies frequencies while maintaining thermal stability.

Thus, there is a need for providing a LiDAR device including a silicon optical phased array, where the above-mentioned conventional distance measurement method is enhanced, which is advantageous to mass production.

### SUMMARY

Embodiments provide a LiDAR device based on a distance measurement scheme using a self-heterodyne scheme which does not include a laser to facilitate measurement of a longer distance than a conventional distance measurement scheme by increasing the receive sensitivity of a reception light source and need accurate frequency control.

In detail, embodiments provide a LiDAR device for mixing a reception light source received after being reflected from an object with a coherent reference optical signal having a high power, beating the mixed signal to generate an amplified electrical signal having a beat frequency, and measuring a distance to the object based on the generated electrical signal.

Furthermore, embodiments provide a LiDAR device which is economical and efficient because accurate, linear frequency conversion for a light source is not required like a conventional FMCW scheme.

Embodiments provide a LiDAR device based on a silicon optical phased array (Si-OPA) of high integration and low power, which facilitates high-integration mass production.

At this time, embodiments provide a LiDAR device having low structure complexity by removing an optical coupler with a silicon optical phased array or an optical splitter connected with an optical heterodyne detector as a balance optical detector included in the optical heterodyne detector is implemented as a silicon photon assisted tunneling photodetector (Si-PAT-PD) in the form of an optical waveguide optical detector.

Furthermore, embodiments provide a LiDAR device which efficiently has a scanning range where a transmission light source is radiated to an object by including a switch for selecting any one of silicon optical phased arrays, each of which has a different scanning range, and connecting an optical waveguide with the selected silicon optical phased array.

According to an exemplary embodiment, a LiDAR device may include a light generator that generates a continuous coherent transmission light source having a first frequency in a specific interval and delivers a time when frequency modulation into the first frequency is performed to a distance measurement circuit, an optical transmitter that delivers the transmission light source, delivered from the light generator, to an optical heterodyne detector and radiates the transmission light source to an object in free space, an optical receiver that receives a reception light source where the transmission light source is reflected from the object, the optical heterodyne detector that outputs an electrical signal of a beat frequency based on the transmission light source delivered from the light generator and the reception light source delivered from the optical receiver, and the distance measurement circuit that measures a distance to the object based on the electrical signal of the beat frequency delivered from the optical heterodyne detector and the frequency modulation time delivered from the light generator.

According to an aspect, the light generator may include a light source that generates the transmission light source, a lasing frequency of which is changed; and a light source driver that changes a driving current such that the lasing frequency of the light source is changed and supplies the changed driving current to the light source The optical transmitter may include an optical splitter that splits and outputs the transmission light source, delivered from the light source, to a transmission optical phased array and the optical heterodyne detector and the transmission optical phased array that splits the transmission light source, delivered from the optical splitter, into multiple channels, adjusts an inter-channel phase to determine a signal transmission direction, and radiates the transmission light source to the object. The optical receiver may include a receive optical phased array that adjusts an inter-channel phase to determine a signal reception direction, collects the reception light source, and delivers the reception light source to the optical heterodyne detector. The LiDAR device may further include a controller that adjusts an inter-channel phase of each of the transmission optical phased array and the receive optical phased array to determine a signal transmission and reception direction and provides a distance measurement initiation signal to the light source driver and the distance measurement circuit.

According to another aspect, the light source may be implemented as a distributed feedback laser (DEB) laser, a lasing frequency of which is linearly changed by e driving current supplied from the light source driver.

According to another aspect, the light source driver may be composed of a direct modulation driver chip implemented as a semiconductor to supply a driving current corresponding to the distance measurement initiation signal, received from the controller, to the light source.

According to another aspect, the transmission optical phased array and the receive optical phased array may be implemented as a single configuration part.

According to another aspect, the optical heterodyne detector may include a directional optical coupler that mixes the transmission light source delivered from the light generator and the reception light source delivered from the optical receiver and a balance optical detector that detects an optical signal delivered from the directional optical coupler and outputs the electrical signal of the beat frequency.

According to another aspect, the balance optical detector may be implemented as a silicon photon assisted tunneling photodetector (Si PAT-PD) in the form of an optical waveguide optical detector that obtains photocurrent using a photon assisted tunneling effect by a reverse bias voltage applied to a p-n junction structure of a silicon waveguide.

According to another aspect, any one of the optical heterodyne detector or the distance measurement circuit may include a transimpedance amplifier (TIA) that converts the electrical signal output from the balance optical detector into a voltage signal and amplify the voltage signal and an envelope detector that detects an envelope from a voltage signal having the beat frequency.

According to another aspect, any one of the optical heterodyne detector or the distance measurement circuit further may include a band filter that passes and outputs only an intermediate frequency band, in the voltage signal having the beat frequency delivered from the transimpedance amplifier, to the envelope detector.

According to another aspect, the optical splitter, the transmission optical phased array, the receive optical phased array, the directional optical coupler, and the balance optical detector may the integrated into a single silicon optical chip.

According to another aspect, the distance measurement circuit may include a comparator that compares a time when the electrical signal of the beat frequency is generated with the time when the frequency modulation into the first frequency is performed and a distance time calculator that measures a time of flight of the transmission light source based on a difference between the time when the electrical signal of the beat frequency is generated and the time when the frequency modulation into the first frequency is performed, the times being compared by the comparator, and calculates the distance to the object using the time of flight of the transmission light source.

According to another aspect, the time when the electrical signal of the beat frequency may be a time when the optical receiver receives the reception light source.

According to an exemplary embodiment, a method for measuring a distance in a LiDAR device including a light generator, an optical transmitter, an optical receiver, an optical heterodyne detector, and a distance measurement circuit may include generating, by the light generator, a continuous coherent transmission light source having a first frequency in a specific interval and delivering, by the light generator, a time when frequency modulation into the first frequency is performed to the distance measurement circuit, delivering, by the optical transmitter, the transmission light source, delivered from the light generator, to the optical heterodyne detector and radiating, by the optical transmitter, the transmission light source to an object in free space, receiving, by the optical receiver, a reception light source where the transmission light source is reflected from the object, outputting, by the optical heterodyne detector, an electrical signal of a beat frequency based on the transmission light source delivered from the light generator and the reception light source delivered from the optical receiver, and measuring, by the distance measurement circuit, a distance to the object based on the electrical signal of the beat frequency delivered from the optical heterodyne detector and the frequency modulation time delivered from the light generator.

According to an exemplary embodiment, a LiDAR device may include a light generator that generates a continuous coherent transmission light source having a first frequency in a specific interval and delivers a time when frequency modulation into the first frequency is performed to a distance measurement circuit, an optical splitter that splits and outputs the transmission light source, delivered from the light source, to a transmission optical phased array and a directional optical coupler, the transmission optical phased array that splits the transmission light source, delivered from the optical splitter, into multiple channels, adjusts an inter-channel phase to determine a signal transmission direction, and radiates the transmission light source to the object, a receive optical phased array that adjusts an inter-channel phase to determine a signal reception direction, receives a reception light source where the transmission light source is reflected from the object, and delivers the reception light source to the directional optical coupler, the directional optical coupler that mixes the transmission light source delivered from the optical splitter and the reception light source delivered from the receive optical phased array, a balance optical detector that detects an optical signal delivered from the directional optical coupler and outputs an electrical signal of a beat frequency, and the distance measurement circuit that measures a distance to the object based on the electrical signal of the beat frequency delivered from the balance optical detector and the frequency modulation time delivered from the light generator. The optical splitter, the transmission optical phased array, the receive optical phased array, the directional optical coupler, and the balance optical detector may be integrated into a single silicon optical chip.

Embodiments provide a LiDAR device based on a distance measurement scheme using a self-heterodyne scheme which does not include a laser to facilitate measurement of a longer distance than a conventional distance measurement scheme by increasing the receive sensitivity of a reception light source and need accurate frequency control.

In detail, embodiments provide a LiDAR device for mixing a reception light source received after being reflected from an object with a coherent reference optical signal having a high power, beating the mixed signal to generate an amplified electrical signal having a beat frequency, and measuring a distance to the object based on the generated electrical signal.

Furthermore, embodiments provide a LiDAR device which is economical and efficient because accurate, linear frequency conversion for a light source is not required like a conventional FMCW scheme.

Embodiments provide a LiDAR device based on a silicon optical phased array (Si-OPA) of high integration and low power, which facilitates high-integration mass production.

At this time, embodiments provide a LiDAR device having low structure complexity by removing an optical coupler with a silicon optical phased array or an optical splitter connected with an optical heterodyne detector as a balance optical detector included in the optical heterodyne detector is implemented as a silicon photon assisted tunneling photodetector (Si-PAT-PD) in the form of an optical waveguide optical detector.

Furthermore, embodiments provide a LiDAR device which efficiently has a scanning range where a transmission light source is radiated to an object by including a switch for selecting any one of silicon optical phased arrays, each of which has a different scanning range, and connecting an optical waveguide with the selected silicon optical phased array.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIGS. 1A and 1B are drawings illustrating a LiDAR device and behavior over time in an optical signal transmitted and received by the LiDAR device according to an embodiment.

FIGS. 2A and 2B are drawings illustrating behavior over time in a transmission light source and behavior over time in an electrical signal, a reception light source of which is detected, to compare and describe a method for measuring a time of flight using self-heterodyne detection according to an embodiment with a conventional method for measuring a time of flight using direct detection;

FIGS. 3A and 3B are drawings illustrating a structure implemented such that a LiDAR device includes a silicon optical phased array implemented in a silicon optical chip, according to an embodiment,

FIG. 4 is a drawing illustrating a detailed functional configuration of a distance measurement circuit included in a LiDAR device according to an embodiment;

FIG. 5 is a drawing illustrating a variable characteristic of a lasing frequency according to a change in operating current when a light source is implemented as a DFB laser, according to an embodiment;

FIGS. 6A and 6B are drawings illustrating structures of a silicon-based optical splitter and a silicon-based directional optical coupler, in which a LiDAR device is implemented in a silicon optical chip, according to an embodiment;

FIGS. 7A and 7B are drawings illustrating a receive power gain obtained by dividing power Obtained for each structure provided in FIGS. 6A and 6B by a power of a direct detection scheme to describe an effect of amplifying a reception light source in a self-heterodyne detection scheme of a LiDAR device, according to an embodiment; and

FIG. 8 is a drawing illustrating a structure of a balance optical detector when the balance optical detector included in a LiDAR device is implemented as an Si PAT-PD, according to an embodiment.

### DETAILED DESCRIPTION

Advantages, features, and methods of accomplishing the same will become apparent with reference to embodiments described in detail below together with the accompanying drawings. However, the inventive concept is not limited by embodiments disclosed hereinafter, and may be implemented in various forms. Rather, these embodiments are provided to so that this disclosure will be through and complete and will fully convey the concept of the invention to those skilled in the art, and the inventive concept will only be defined by the appended claims.

Terms used in the specification are used to describe embodiments of the inventive concept and are not intended to limit the scope of the inventive concept. In the specification, the terms of a singular form may include plural forms unless otherwise specified. The expressions “comprise” and/or “comprising” used herein indicate existence of one or more other components, steps, operations, and/or elements other than stated, components, steps, operations, and/or elements but do not exclude presence of additional elements.

Unless otherwise defined herein, all terms (including technical and scientific terms) used in the specification may have the same meaning that is generally understood by a person skilled in the art. Also, terms which are defined in a dictionary and commonly used should be interpreted as not in an idealized or overly formal detect unless expressly so defined.

Hereinafter, a description will be given in detail of exemplary embodiments of the inventive concept with reference to the accompanying drawings. Like reference numerals are used for the same components shown in each drawing, and a duplicated description of the same components will be omitted.

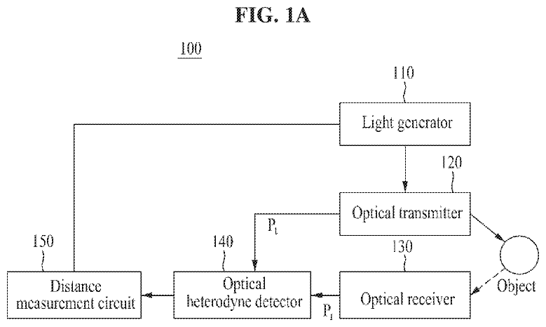

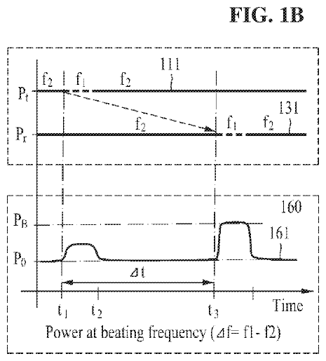

FIGS. 1A and 1B are drawings illustrating a LiDAR device and behavior over time in an optical signal transmitted and received by the LiDAR device according to an embodiment. In detail, FIG. 1A is a block diagram illustrating a LiDAR device according to an embodiment. FIG. 1B is a drawing illustrating behavior over time in an optical signal transmitted and received by a LiDAR device shown in FIG. 1A.

Referring to FIGS. 1A and 1B, a LiDAR device 100 according to an embodiment may include a light generator 110, an optical transmitter 120, an optical receiver 130, an optical heterodyne detector 140, and a distance measurement circuit 150. Hereinafter, the components of the LiDAR device 100 may be connected to each other through an optical waveguide, but not limited thereto. When components of each of the optical transmitter 120, the optical receiver 130, and the optical heterodyne detector 140 are integrated into a single silicon optical chip, an optical waveguide for connecting the components of each of the optical transmitter 120, the optical receiver 130, and the optical heterodyne detector 140 may be omitted.

The light generator 110 may generate a continuous coherent transmission light source having a first frequency in a specific interval and may deliver a first time t₁ which is a time when frequency modulation into the first frequency is performed to the distance measurement circuit 150.

The light generator 110 may generate and deliver a coherent light source, a frequency of which is converted over time, to the optical splitter 120. In detail, the light generator 110 may generate the transmission light source, a frequency of which is converted to have the first frequency f₁ from the first time t₁ when distance measurement is initiated to a second time t₂ and have a second frequency f₂ at the second time t₂.

As such, characteristics of the wavelength and power of the transmission light source generated and transmitted by the light generator 110 are represented as graph 111. For convenience of description, a delay time for delivering the transmission light source between an element and an element, which constitute the LiDAR device, is not considered, Referring to graph 111, the light generator 110 may generate the second frequency using a lasing frequency, may convert the second frequency into the first frequency at the first time when distance measurement is initiated to maintain the first frequency, and may convert the first frequency into the second frequency at the second frequency. The light generator 110 may maintain the second frequency until a time when next distance measurement is initiated, and the process described above may be repeated.

Such a light generator 110 may include a light source (not shown) and a light source driver (not shown). The light source may generate a transmission light source, a lasing frequency of which is changed, (in detail, generate a transmission light source having the first frequency at the first time and generate a transmission light source having the second frequency at the second time). The light source driver may change a driving current, such that a lasing frequency of the light source is changed, and may supply the changed driving current to the light source.

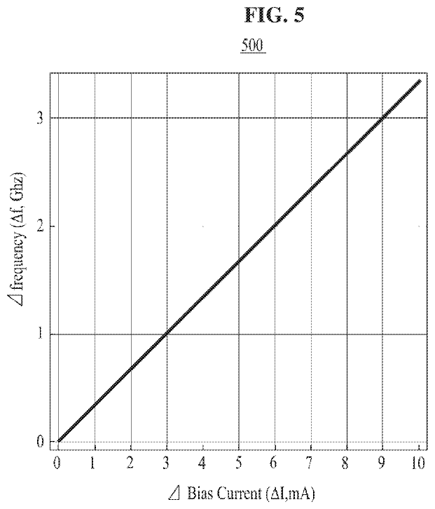

At this time, the light source may be implemented as a distributed feedback laser (DFB), a lasing frequency of which is linearly changed by the driving current supplied from the light source driver. It will be described in detail with reference to FIG. 5.

Furthermore, the light source driver may be composed of a direct modulation driver chip implemented with a semiconductor to supply a driving current corresponding to distance measurement initiation, which is received from a controller (which is a component for controlling an overall operation of the LiDAR device 100, for example, for adjusting an inter-phase phase of each of a transmission optical phased array and a receive optical phased array to determine a signal transmission and reception direction and providing a distance measurement initiation signal to the light source driver and the distance measurement circuit 150, which is not shown in FIG. 1A), to the light source.

The optical transmitter 120 may deliver the transmission light source, delivered from the light generator 110, to the optical heterodyne detector 140 and may irradiate the transmission light source to an object in free space. In detail, as the optical transmitter 120 is composed of an optical splitter (not shown) and a transmission optical phased array (not shown), it may split and output the transmission light source, delivered from the light source, to the transmission optical phased array and the optical heterodyne detector 140 via the optical splitter and may split the transmission light source delivered from the optical splitter, into multiple channels via the transmission optical phased array, adjust an inter-channel phase to determine a signal transmission direction, and may irradiate the transmission light source to the object.

As such, the transmission light source, which is generated by the light generator 110 and is delivered to the optical heterodyne detector 140 via the optical splitter, may be a reference optical signal having a power of Pₜ, which may be used in the optical heterodyne detector 140. According to graph ill, powers of the transmission light sources which oscillate between the first frequency and the second frequency may be the same as each other, but not limited thereto.

The transmission light source, which is generated by the light generator 110 and is radiated to the object via the transmission optical phased array through the optical splitter, may be reflected from the object. The optical receiver 130 may receive a reception light source reflected from the object (hereinafter, the reception light source refers to an optical signal which is reflected from the object and is received by the light receiver 130) and may deliver it to the optical heterodyne detector 140. Herein, the optical receiver 130 may adjust an inter-channel phase to determine a signal reception direction and may collect a reception light source to deliver the collected reception light source to the optical heterodyne detector 140.

The transmission optical phased array and the receive optical phased array respectively included in the optical transmitter 120 and the optical receiver 130 may have a grid array antenna structure to adjust an inter-channel phase or a structure including a slab region of p- or n-type doping between antenna arrays.

Referring to graph 131 indicating behavior over time in the reception light source delivered from the optical receiver 130 to the optical heterodyne detector 140, an optical signal having the first frequency, which is generated by the light generator 110 at the first time, may be delayed by a path from the optical transmitter 120 to the object and from the object to the optical receiver 130 and may be delivered to the optical heterodyne detector 140 at a third time t₃. Herein, the third time is a time when the optical receiver 130 receives the reception light source, which refers to a time when an electrical signal (a beat signal) having a beat frequency is generated by the optical heterodyne detector 140.

At this time, a power Pᵣ of the received optical signal delivered to the optical heterodyne detector 140 includes all loss generated in the process of delivering and reflecting the optical signal. According to graph 160 of Input optical signals input to the optical heterodyne detector 140 (the transmission light source which is generated by the light generator 110 and is delivered via the optical splitter and the reception light source delivered from the optical receiver 130), the input optical signals may be electrical signals represented as Equations 1 to 3 below, which may be delivered to the distance measurement circuit 150.

Pₜ=|eₜ|²=|\sqrt{Pₜ}e^{j(2πf}^{₁}^{t)}|², Pᵣ=|eᵣ|²=|\sqrt{Pᵣ}e^{j(2πf}^{₂}^{t)}|² [Equation 1]

In Equation 1 above, eₜ refers to an electric field of the reference optical signal having the second frequency and a power of Pₜ (the transmission light source which is generated by the light generator 110 and is delivered via the optical splitter), and eᵣ refers to an electric field of the reception light source having the first frequency and a power of Pᵣ.

The optical heterodyne detector 140 may output an electrical signal (a beat signal) of a beat frequency based on the transmission light source delivered from the light generator 110 and the reception light source delivered from the optical receiver 130. In detail, the optical heterodyne detector 140 may include a directional optical coupler (not shown) and a balance optical detector (not shown).

The directional optical coupler may mix the transmission light source delivered from the light generator 110 (more accurately, the optical splitter included in the light generator 110) and the reception light source delivered from the optical receiver 130 to deliver the mixed signal to the balance optical detector.

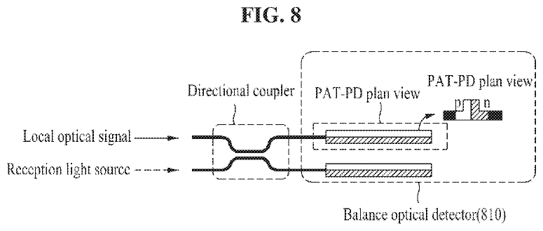

The balance optical detector may detect the optical signal delivered from the directional optical coupler to output an electrical signal of a beat frequency. For example, the balance optical detector may output an alternating current (AC) signal having a beat frequency which is a difference between the first frequency the reception light source has and the second frequency the transmission light source has, using coherence between the reception light source and the transmission light source. Particularly, the balance optical detector may be implemented as a silicon photon assisted tunneling photodetector (Si PAT-PD) in the form of an optical waveguide optical detector which applies a reverse bias voltage applied to a p-n junction structure of a silicon waveguide and obtains photocurrent using a photon assisted tunneling effect. It will be described in detail with reference to FIG. 8.

In the optical heterodyne detector 140 of such a structure, as the directional optical coupler adds electric fields of the reference optical signal (the transmission light source) and the reception light source and as the balance optical detector generates photocurrent proportional to a power of a beat signal from the signal in which the electric fields are added in the directional optical coupler, a power of the photocurrent (the AC signal) output from the balance optical detector may be represented as Equation 2 below.

\tilde{P}_{B}=2R²PₜPᵣ Cos(2πΔf) [Equation 2]

In Equation 2 above, R refers to optical responsivity in a typical optical detector. Power \tilde{P}_{B} by the photocurrent generated by the balance optical detector may have magnitude proportional to multiplication of the beat frequency Δf, which is a difference between the first frequency and the second frequency input to the optical heterodyne detector 140, the reference optical signal, and the reception light source. The AC signal having the generated power \tilde{P}_{B} may be delivered to a typical envelop detector included in the optical heterodyne detector 140. The envelope detector may convert the electrical signal having the beat frequency into a base signal P_{B} having a power of PₜPᵣ like Equation 3 below and may detect an envelope from the base signal.

P_{B}=|\tilde{P}_{B}|=R²PₜPᵣ [Equation 3]

Hereinafter, a method for measuring a distance in the LiDAR device 100 according to an embodiment and characteristics of an electrical signal including distance information will be described with reference to graph 161 indicating behavior over a time in the electrical signal generated by the optical heterodyne detector 140. As shown in graph 161, the reference optical signal and the reception light source are continuously input to the optical heterodyne detector 140. Herein, the electrical signal output from the optical heterodyne detector 140 may represent power detected at the heat frequency between the first frequency and the second frequency.

Thus, because there is no first frequency at a time before distance measurement is initiated (at a time before the first time) P₀ detected at a beating frequency is 0. Because the reference optical signal is able to have the first frequency and the reception light source is able to have the second frequency, between from the first time when distance measurement is initiated, to the second time when the first frequency is continuous, a rising power P_{B} at the beat frequency like graph 161 may be detected. However, this due to a change in the frequency of the reference optical signal rather than the reception light source is not referenced for distance measurement. Because the second frequency is input from the reference optical signal after the second time, P₀ is kept again. The power kept P₀ is beaten with the reference optical signal of the second frequency at the third time when the reception light source of the first frequency, which is reflected from the object, reaches the optical heterodyne detector 140, thus greatly increasing to P_{B} to be detected.

Thus, when measuring a difference Δt between the first time and the third time, a distance to the object may be calculated. The distance measurement circuit 150 may measure the distance to the object based on the electrical signal of the beat frequency delivered from the optical heterodyne detector 140 and the frequency modulation time delivered from the light generator 110. To this end, the distance measurement circuit 150 may be configured to include a comparator (not shown) for comparing the third time when the electrical signal of the beat frequency is generated with the first time when frequency conversion into the first frequency is performed and a time distance calculator for measuring a time of flight of the transmission light source based on a difference between the third time when the electrical signal of the beat frequency is generated and the first time when the frequency modulation into the first frequency is performed, which are compared by the comparator, and for calculating a distance to the object using the time of flight of the transmission light source.

At this time, the envelop detector is described as being included in the optical heterodyne detector 140, but the envelope detector may be included in the distance measurement circuit 150 rather than the optical heterodyne detector 140. In any case, the comparator included in the distance measurement circuit 150 may compare a signal (the base signal P_{B}) having a rising state at the third time delivered from the envelope detector with a signal where distance measurement is initiated at the first time.

Furthermore, the optical heterodyne detector 140 may further include a transimpedance amplifier (TEA) (not shown) for converting the AC signal output from the balance optical detector into a voltage signal and amplifying the voltage signal and a band filter (not shown) for passing and outputting only an intermediate frequency band in the voltage signal having the heat frequency, delivered from the TIA, to the envelope detector. The TIA and the band filter may be included in the distance measurement circuit 150 rather than the optical heterodyne detector 140.

The electrical signal observed at the third time may be represented at a magnitude where a power Pₜ of the reference optical signal is amplified with respect to a power Pᵣ of the reception light source. In general, inasmuch as the power of the reference optical signal is much greater than the power of the reception light source, a few times to several tens of times gains may be obtained.

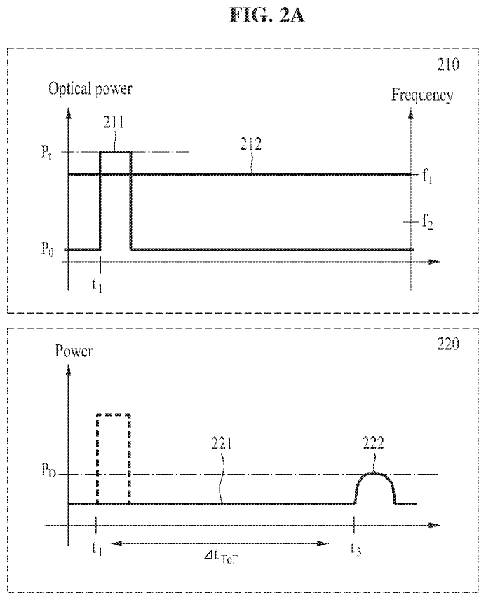

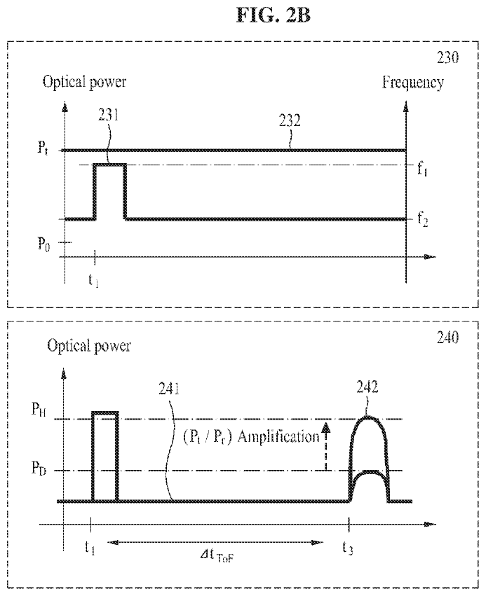

Hereinafter, a method for measuring a time of flight using self-heterodyne detection according to an embodiment and a conventional method for measuring a time of flight using direct detection are compared and described with reference to FIGS. 2A and 2B.

FIGS. 2A and 2B are drawings illustrating behavior over time in a transmission light source and behavior over time in an electrical signal, a reception light source of which is detected, to compare and describe a method for measuring a time of flight using self-heterodyne detection according to an embodiment with a conventional method for measuring a time of flight using direct detection. In detail, FIG. 2A is a drawing illustrating behavior over time in a transmission light source and behavior over time in an electrical signal, a reception light source of which is detected, in a conventional method for measuring a time of flight using direct detection. FIG. 2B is a drawing illustrating behavior over time in a transmission light source and behavior over time in an electrical signal generated by self-heterodyne detection, in a method for measuring a time of flight using self-heterodyne detection according to an embodiment.

Referring to FIG. 2A, behavior 210 over time a transmission light source and behavior 220 over time in an electrical signal generated after the reception light source is directly detected, in the conventional method for measuring a time of flight using direct detection, are shown in the drawing.

To distinguish a time of a reception light source where a transmission light source is reflected from an object and is received, an optical pulse 211, a power of which is changed, is used. Because a frequency 212 of the transmission light source used at this time is not used for distance measurement, it is not limited in the range of not having an influence on a component or connection. The transmission light source may be generated as a power of Pₜ at a first time t₁ which is a time when distance measurement is initiated and is then maintained until a second time t₂, and may maintain a power of P₀ from the second time to a time when next distance measurement is initiated. At this time, P₀ may be 0 to reduce interruption of the reception of the reception light source reflected from the object.

Because the reception light source uses a conventional optical detector of a direct detection scheme for generating a current signal proportional to the power, a power of a receive electrical signal may be represented as Equation 4 below.

P_{D}=(RPᵣ)² [Equation 4]

In Equation 4 above, P_{D} refers to the power of the receive electrical signal, Pᵣ refers to the power of the received optical signal, and R refers to optical responsivity. Referring to graph 220, while the electrical signal generated by the detection of the reception light source maintains a low power 221 from a first time which is a time when distance measurement is initiated, as the optical signal emitted at the first time is received at a power of Pᵣ, a power 222 of the electrical signal detected according to Equation 4 above increases to P_{D}. Thus, a third time when the optical signal emitted at the first signal is reflected and returned may be measured. When measuring a difference Δt between the first time and the third time, a distance to an object may be calculated.

Referring to FIG. 2B, behavior 230 over time a transmission light source and behavior 240 over time in an electrical signal generated after the reception light source is self-heterodyne detected, in the method for measuring a time of flight using self-heterodyne detection according to an embodiment, are shown in the drawing.

Unlike the above-mentioned conventional direct detection method, a frequency pulse 231, a frequency of which is changed, is used to distinguish a time when the transmission light source is reflected and reached, and at this time, a power change in the power 232 used in the conventional direct detection method is not used. A process, where the transmission light source is generated as a second frequency as a lasing frequency, is converted and maintained into a first frequency f₁ at the first time t₁ when distance measurement is initiated, is converted into the second frequency again at a second time t₂, and is maintained as the second frequency until next distance measurement is initiated, may be repeated.

Behavior over time in an electronic signal, in which the reception light source and the reference optical signal are generated by self-heterodyne detection, is shown in graph 240. According to Equations 1 to 3 above, there is no power 241 at a beat frequency before the third time when the optical signal emitted at the first frequency at the first time is received, and an electrical signal having a power 242 of P_{H}(=RPₜPᵣ) is generated at the third time. Thus, the third time when the optical signal emitted at the first time is reflected and returned may be measured. When measuring a difference Δt between the first time and the third time, a distance to an object may be calculated.

Comparing power by the self-heterodyne detection according to an embodiment with power P_{H}(=R²Pᵣ²) by the conventional direct detection, the power based on the self-heterodyne detection according to an embodiment is power amplified by Pₜ/Pᵣ. In general, Inasmuch as the reference power is much greater than the receive power, a few times to several tens of times gains may be obtained.

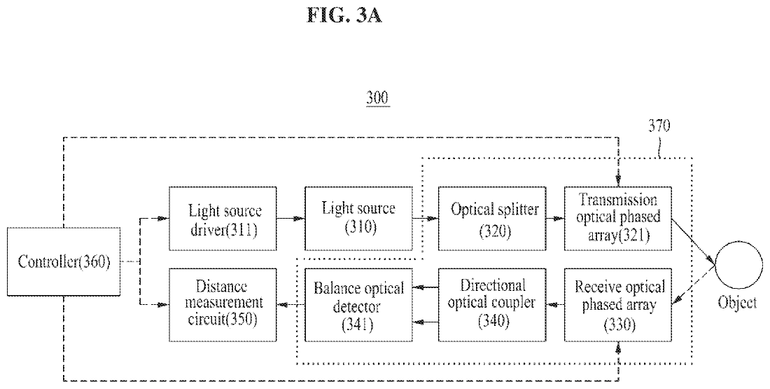

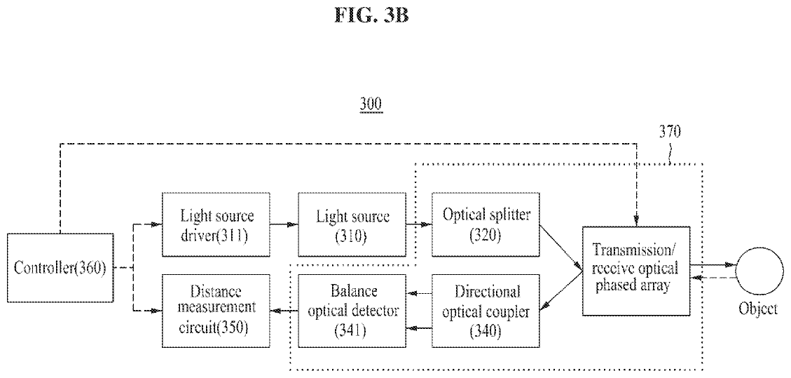

FIGS. 3A and 3B are drawings illustrating a structure implemented such that a LiDAR device includes a silicon optical phased array implemented in a silicon optical chip, according to an embodiment. In detail, FIG. 3A is a drawing illustrating a structure of a LiDAR device shown to include components included in each of a light generator, an optical transmitter, and an optical heterodyne detector described in FIG. 1A, and FIG. 3B is a drawing illustrating a structure where a transmission optical phased array and a receive optical phased array are implemented as a single configuration part.

Referring to FIG. 3A, a LiDAR device 300 may include a light source 310, a light source driver 311, an optical splitter 320, a transmission optical phased array 321, a receive optical phased array 330, a directional optical coupler 340, a balance optical detector 341, a distance measurement circuit 350, and a controller 360. Herein, the optical splitter 320, the transmission optical phased array 321, the receive optical phased array 330, the directional optical coupler 340, and the balance optical detector 341 may be implemented on a single silicon optical chip 370.

The light source driver 311 in the LiDAR device 300 may change a driving current such that a lasing frequency of the light source 310 disposed outside the silicon optical chip 370 is changed and may supply the changed driving current the light source 310.

Thus, the light source 310 may generate and deliver a transmission light source, the lasing frequency of which is changed, (the transmission light source having a first frequency at a first time and having a second frequency at a second time) to the silicon optical chip 370.

The silicon optical chip 370 may radiate the delivered transmission light source to an object, may receive a reception light source reflected from the object to convert the reception light source into an electrical signal, and may provide the distance measurement circuit 350 with the electrical signal.

In detail, the optical splitter 320 included in the silicon optical chip 370 may split and deliver the transmission light source, delivered from the light source 310, to the transmission optical phased array 321 and the directional optical coupler 340. The transmission optical phased array 321 may split the transmission light source into multiple channels, may adjust an inter-channel phase to determine a signal transmission direction, thus radiating the transmission light source to free space. The receive optical phased array 330 may adjust an inter-channel phase to determine a signal reception direction and may collect a reception light source to deliver the collected reception light source to the directional optical coupler 340.

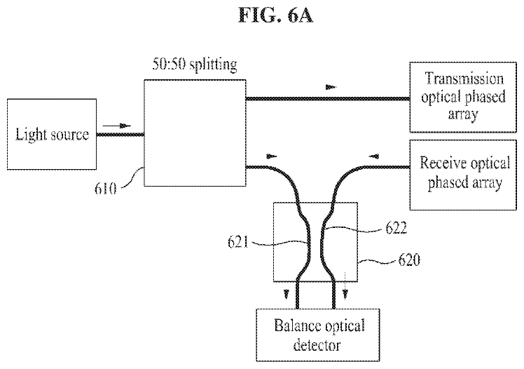

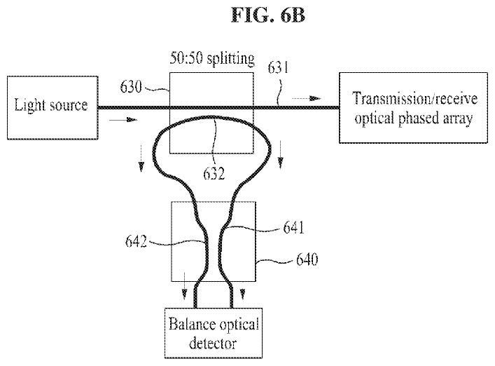

The directional optical coupler 340 may divide the transmission light source received from the optical splitter 320 into two to be delivered to two output ports (two silicon waveguides) and may divide the reception light source delivered from the receive optical phased array 330 into two to be delivered to two output ports, thus mixing the transmission light source and the reception light source and delivering a signal having a phase difference of a half wavelength between the two output ports to the balance optical detector 341 through the two output ports. As the balance optical detector 341 is implemented as an Si PAT-PD for generating photocurrent having a beat frequency which is a frequency difference between the reception light source and the transmission light source from an optical signal in which the reception light source and the transmission light source delivered from the directional optical coupler 340 are added, it may block a DC current from the photocurrent and may output only an AC current to the distance measurement circuit 350 by connecting two silicon-based optical detectors constituting the Si PAT-PD. It will be described in detail with reference to FIG. 8. The optical splitter 320 and the directional optical coupler 340 will be described in detail with reference to FIGS. 6A and 6B.

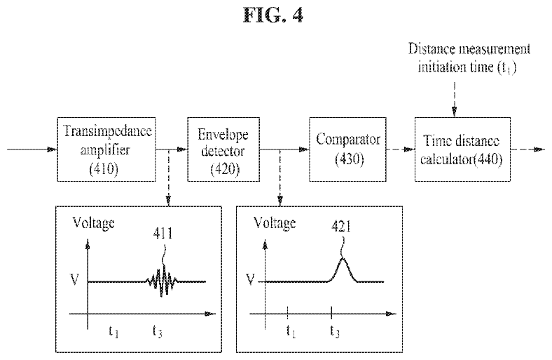

The distance measurement circuit 350 may detect an envelope from a voltage signal converted by amplifying the AC current output from the silicon optical chip 370 (accurately, the balance optical detector 341) and may compare a first time when distance measurement is initiated with a third time when a reception light source where a transmission light source transmitted at an initiation time is reflected from an object is received to measure a distance to the object. It will be described in detail with reference to FIG. 4 below.

In such an operation of the LiDAR device 300, generating the signal for initiating the distance measurement and providing the signal to the light source driver 311 and the distance measurement circuit 350 and controlling the radiation direction of the silicon optical phased arrays 321 and 330 (adjusting steering) may be performed by the controller 360.

As described above, it is shown that the transmission optical phased array 321 and the receive optical phased array 330 are implemented independently, but they are implemented as one configuration part.

FIG. 4 is a drawing illustrating a detailed functional configuration of a distance measurement circuit according to an embodiment. In detail, FIG. 4 is a drawing illustrating a detailed functional configuration of a distance measurement circuit show in FIGS. 3A and 3B.

Referring to FIG. 4, a distance measurement circuit 350 may be implemented to include, but is not limited to, a transimpedance amplifier 410 and an envelope detector 420, and may be implemented to include only components (a comparator 430 and a time distance calculator 440) except for the transimpedance amplifier 410 and the envelope detector 420. In such a case, the transimpedance amplifier 410 and the envelope detector 420 may be included in an optical heterodyne detector.

The transimpedance amplifier 410 included in distance measurement circuit 350 may amplify an AC current having a beat frequency output from a balance optical detector shown in FIGS. 3A and 3B to be converted into a voltage signal 411. The envelope detector 420 included in the distance measurement circuit 350 may remove a high-frequency signal of the voltage signal output from the transimpedance amplifier 410 to detect and output only an envelope 421.

Thus, the comparator 430 included in the distance measurement circuit 350 may detect a level of the output envelope 421 and may compare a first time when distance measurement is initiated (a time when frequency modulation into a first frequency is performed) with a third time when a reception light source where a transmission light source transmitted at an initiation time is reflected from an object is received (a time when an electrical signal of a beat frequency is generated). The time distance calculator 440 may measure a time of flight of the transmission light source based on a difference between the first time and the third time and may calculate and measure a distance to the object using the time of flight of the transmission light source.

FIG. 5 is a drawing illustrating a variable characteristic of a lasing frequency according to a change in operating current when a light source is implemented as a DEB laser, according to an embodiment.

A distributed feedback (DFB) laser for linearly changing a frequency which oscillates by current supplied from a light source driver may be used as a light source described above with reference to FIG. 1A and FIGS. 3A and 3B.

In this regard, referring to FIG. 5, the light source should be able to modulate a lasing frequency through external control while maintaining coherence. Thus, the DFB laser may have a characteristic of changing an operating current depending on a relationship of FIG. 5 below to linearly modulate the lasing frequency.

$$Δ f = \frac{α \times κ}{4 π} s Δ I \qquad [ Equation 5 ]$$

In Equation 5 above, Δf refers to the amount of change of the lasing frequency, α refers to the linewidth enhancement factor of the DFB laser, κ refers to the chirp coefficient of the DFB laser, and s refers to the slop efficiency of the DFB layer. In Equation 5 above, the amount of frequency Δf (Ghz) for the amount of change of current ΔI (mA) which substitutes 3.5, 4.8×10¹² Hz/W, and 0.25, which are representative values observed by a typical DFB laser, as values of α, κ, and s, is shown in graph 500.

As shown in the graph, the DFB laser may obtain a modulated optical signal of 1 Ghz through a change in operating current of about 3 mA. Inasmuch as a typical DFB laser has a fast operating speed, it may be used as a light source of a LiDAR device using the proposed self-heterodyne detection.

FIGS. 6A and 6B are drawings illustrating structures of a silicon-based optical splitter and a silicon-based directional optical coupler, in which a LiDAR device is implemented in a silicon optical chip, according to an embodiment. The structures shown in FIGS. 6A and 6B are based on silicon integrated optics of forming an optical waveguide by forming a core using high refractive index silicon and cladding low refractive index Silica. However, such structures are not limited to the silicon integrated optics and are applicable to various materials such as silicon oxide, silicon nitride, and compound semiconductor.

Referring to FIG. 6A indicating a structure including a multimode interference optical splitter 610 and a directional optical coupler 620, which is applicable to a structure where a transmission optical phased array and a receive optical phased array are separated as shown in FIG. 3A, a transmission light source delivered by a single mode waveguide from a light source is combined in a multimode in an area of the optical splitter 610, where a waveguide is expanded, to form a multimode interference pattern by a self-imaging theory. Thus, when an output waveguide is disposed in an area where the pattern is generated, the optical splitter 610 having any splitting ratio may be formed.

Because a light splitting ratio in the area of the optical splitter 610 is determined by a distance of an interference interval, it may be adaptively changed at the ratio of 50:50 according to an embodiment or at the ratio of α:(1−α) in consideration of performance of the LiDAR device. Because a first optical waveguide 621 and a second optical waveguide 622 are disposed close to each other to be overlapped with the counterpart's waveguide in an evanescent mode of a reference optical signal of the first optical waveguide 621 and the reception light source of the second optical waveguide 622, a coupled mode theory where the signal is waveguided and moved to an adjacent waveguide is applicable. In the drawing according to an embodiment, a directional optical coupler 620 for mix and delivering the reference optical signal and the reception light source at the ratio of 50:50 to a balance optical detector is shown.

Referring to FIG. 6B indicating a structure where two directional optical couplers 630 and 640 are connected, in which a transmission optical phased array and a receive optical phased array are implemented as a single configuration part, the first directional optical coupler 630 may split a transmission light source delivered from a light source at the ratio of 50:50 to be provided to a transmission/receive optical phased array and a second optical waveguide 642 of the second directional optical coupler 640. The light splitting ratio may be adaptively changed at the ratio of α:(1−α) consideration of performance of a LiDAR device.

Then, the transmission/receive optical phased array may deliver a reception light source reflected by the object to the first optical waveguide 631 of the first directional optical coupler 630 to which a transmission light source is delivered. The reception light source input to the first optical waveguide 631 may be delivered to a second optical waveguide 632 of the first directional optical coupler 630 by the coupled mode theory and is delivered to a first optical waveguide 641 of the connected second directional optical coupler 640.

As at least a portion of the reception light source delivered to the first optical waveguide 641 of the second directional optical coupler 640 is delivered to the second optical waveguide 642 by the coupled mode theory and as at least a portion of a reference optical signal delivered to the second optical waveguide 642 of the second directional optical coupler 640 is delivered to the first optical waveguide 641, an optical signal in which the reference optical signal and the reception light source are mixed may be delivered to a balance optical detector by the two waveguides.

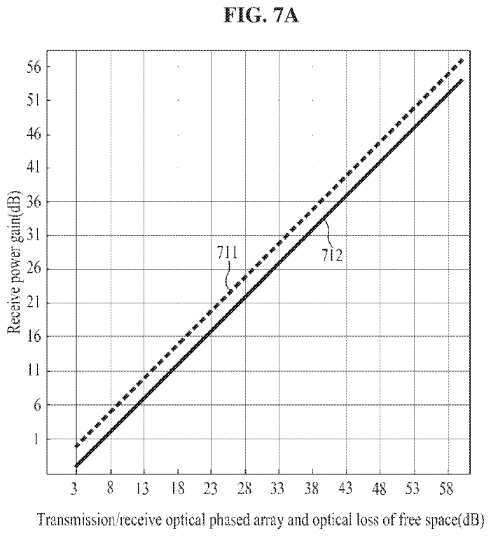

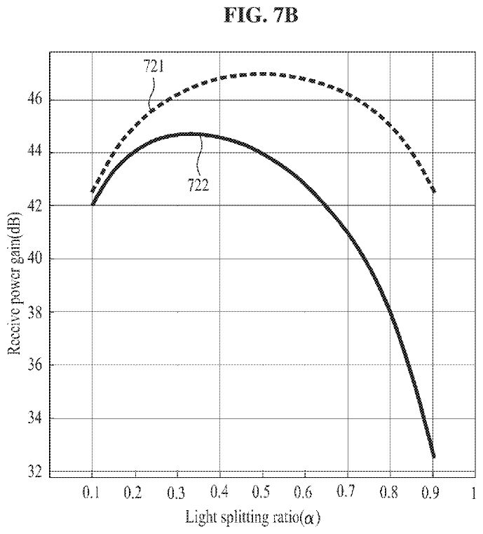

FIGS. 7A and 7B are drawings illustrating a receive power gain obtained by dividing power obtained for each structure provided in FIGS. 6A and 6B by a power of a direct detection scheme describe an effect of amplifying a reception light source in a self-heterodyne detection scheme of a LiDAR device, according to an embodiment. In detail, FIG. 7A is a drawing illustrating a receive power gain for a change in loss which occurs on a path where it is radiated to an object. FIG. 7B is a drawing illustrating a receive power gain according to a light splitting ratio for each structure provided in FIGS. 6A and 6B.

In the structure of FIG. 6A, the receive power gain Gₐ follows Equation 6 below.

$${G}_{a} = \frac{2 α ( 1 - α )}{L} \qquad [ Equation 6 ]$$

In Equation 6 above, Gₐ denotes the receive power gain by the structure of FIG. 6A and the heterodyne detection, a denotes the light splitting ratio of the MMI optical splitter 610 of FIG. 6A, and L denotes all loss which is present on the path where the optical signal split by the MMI optical splitter 610 of FIG. 6A reaches the directional optical coupler 620. Referring to FIG. 7A where it is assumed that the splitting rate a) is 0.5, the receive power gain Gₐ increases as loss increases by Equation 6 above like graph 711. For example, when the receive power gain is 49 dB when the optical path loss is 50 dB, there is an effect where the optical loss decreases to about 25 dB. In other words, when a light source of 10 dBm is used, the same receive power as an input of −15 dBm is received occurs.

In the structure of FIG. 6B, the receive power gain G_{b} follows Equation 7 below.

$${G}_{b} = \frac{2 {α ( 1 - α )}^{2}}{L} \qquad [ Equation 7 ]$$

in Equation 7 above, G_{b} denotes the receive power gain by the structure of FIG. 6A and the heterodyne detection, a denotes the light splitting ratio of the first directional optical coupler 630 of FIG. 6B, and L denotes all loss which is present on the path where the optical signal split by the directional optical coupler 630 of FIG. 6B reaches the first directional optical coupler 630. Referring to FIG. 7B where it is assumed that the splitting ratio is 0.5, the receive power gain Gₐ increases as loss increases by Equation 7 above like graph 712 and has a smaller value by 3 dB than the manner in FIG. 6A. For example, when the receive power gain is 46 dB when the optical path loss is 50 dB, there is an effect where the optical loss decreases to about 23 dB. In other words, when a light source of 10 dBm is used, the same receive power as an input of −18 dBm is received occurs.

FIG. 7B illustrates receive power gains Gₐ 721 and G_{b} 722 according to a slope a when optical loss L is 50 dB in FIGS. 6A and 6B. Gₐ has a maximum value of 46.99 dB when the splitting ratio α is 0.5. G_{b} has a maximum value of 44.71 dB when the splitting ratio α is about 0.33. It may be seen that the splitting ratio obtaining the maximum value of the receive power gain is determined according to a structure irrespective of optical loss L. Equations 6 and 7 above representing a relationship between the splitting ratio and the receive power gain may be modified and applied according to various splitting structures.

FIG. 8 is a drawing illustrating a structure of a balance optical detector when the balance optical detector included in a LiDAR device is implemented as an Si PAT-PD, according to an embodiment.

Referring to FIG. 8, a balance optical detector 810 may be implemented as a silicon photon assisted tunneling photodetector (Si PAT-PD) in the form of an optical waveguide optical detector to generate photocurrent having a beat frequency which is a frequency difference between a reception light source and a transmission light source from an optical signal in which the reception light source and the transmission light source delivered from a directional optical coupler are added.

The Si PAT-PD has a form of typical silicon-based rib waveguide and is formed by performing p-doping of V semiconductor and n-doping of Iii semiconductor in silicon which is an intrinsic semiconductor to form a PN junction surface and forming a metal thin film to supply voltage to the outside. At this time, the PAT-PD may obtain photocurrent using a photon assisted tunneling effect of generating an electrical carrier by means of an electric field although a photon of the wavelength of 1300 nm, which is a wavelength of energy smaller than a bandgap is incident, and detecting a photon, by applying a strong reverse bias voltage to the PN junction surface of a p-n junction structure implemented on a silicon waveguide to form an electric field.

As such, as the balance optical detector is implemented as the PAT-PD, an integral structure where a self-heterodyne detection function is implemented in a single silicon optical chip is possible. Thus, the single silicon optical chip, which is the integral structure including the PAT-PD, may considerably more reduce complexity than a conventional LiDAR device including a balance optical detector which is separated and implemented as a separate chip and may increase a level of integration, thus facilitating an economic, efficient LiDAR.

The above-mentioned LiDAR device may perform a distance measurement method composed of the following steps through the above-mentioned structure.

First step: Step of generating, by a light generator, a continuous coherent transmission light source having a first frequency in a specific interval and delivering, by the light generator, a time when frequency modulation into the first frequency is performed to a distance measurement circuit.

Second step: Step of delivering, by an optical transmitter, the transmission light source, delivered from the light generator, to an optical heterodyne detector and radiating, by the optical transmitter, the transmission light source to an object in free space

Third step: Step of receiving, by an optical receiver, a reception light source where the transmission light source is reflected from the object

Fourth step: Step of outputting, the optical heterodyne detector, an electrical signal of a beat frequency based on the transmission light source delivered from the light generator and the reception light source delivered from the optical receiver

Fifth step: Step of measuring, by the distance measurement circuit, a distance to the object based on the electrical signal of the beat frequency delivered from the optical heterodyne detector and the frequency modulation time delivered from the light generator

A detailed operation at step may include the above-mentioned contents for the structure of the LiDAR device and functions of the respective components.

While a few exemplary embodiments have been shown and described with reference to the accompanying drawings, it will be apparent to those skilled in the art that various modifications and variations can be made from the foregoing descriptions. For example, adequate effects may be achieved even if the foregoing processes and methods are carried out in different order than described above, and/or the aforementioned elements, such as systems, structures, devices, or circuits, are combined or coupled in different forms and modes than as described above or be substituted or switched with other components or equivalents.

Therefore, other implements, other embodiments, and equivalents to claims are within the scope of the following claims.

The foregoing systems and devices may be realized by hardware elements, software elements and/or combinations thereof. For example, the systems, devices, and components illustrated in the exemplary embodiments of the inventive concept may be implemented in one or more general-use computers or special-purpose computers, such as a processor, a controller, an arithmetic logic unit (ALU), a digital signal processor, a microcomputer, a field programmable array (FPA), a programmable logic unit (PLU), a microprocessor or any device which may execute instructions and respond. A processing unit may implement an operating system (OS) or one or software applications running on the OS. Further, the processing unit may access, store, manipulate, process and generate data in response to execution of software. It will be understood by those skilled in the art that although a single processing unit may be illustrated for convenience of understanding, the processing unit may include a plurality of processing elements and/or a plurality of types of processing elements. For example, the processing unit may include a plurality of processors or one processor and one controller. Also, the processing unit may have a different processing configuration, such as a parallel processor.

Software may include computer programs, codes, instructions or one or more combinations thereof and may configure a processing unit to operate in a desired manner or may independently or collectively control the processing unit. Software and/or data may be permanently or temporarily embodied in any type of machine, components, physical equipment, virtual equipment, computer storage media or units or transmitted signal waves so as to be interpreted by the processing unit or to provide instructions or data to the processing unit. Software may be dispersed throughout computer systems connected via networks and may be stored or executed in a dispersion manner. Software and data may be recorded in one or more computer-readable storage media.

The methods according to the above-described exemplary embodiments of the inventive concept may be implemented with program instructions which may be executed through various computer means and may be recorded in computer-readable media. The media may also include, alone or in combination with the program instructions, data files, data structures, and the like. The program instructions recorded in the media may be designed and configured specially for the exemplary embodiments of the inventive concept or be known and available to those skilled in computer software. Computer-readable media include magnetic media such as hard disks, floppy disks, and magnetic tape; optical media such as compact disc-read only memory (CD-ROM) disks and digital versatile discs (DVDs); magneto-optical media such as floptical disks; and hardware devices that are specially configured to store and perform program instructions, such as read-only memory (ROM), random access memory (RAM), flash memory, and the like. Program instructions include both machine codes, such as produced by a compiler, and higher level codes that may be executed by the computer using an interpreter.

While a few exemplary embodiments have been shown and described with reference to the accompanying drawings, it will be apparent to those skilled in the art that various modifications and variations can be made from the foregoing descriptions. For example, adequate effects may be achieved even if the foregoing processes and methods are carried out in different order than described above, and/or the aforementioned elements, such as systems, structures, devices, or circuits, are combined or coupled in different forms and modes than as described above or be substituted or switched with other components or equivalents.

Therefore, other implements, other embodiments, and equivalents to claims are within the scope of the following claims.

What is claimed is:

1. A LiDAR device, comprising:
a light generator configured to generate a continuous coherent transmission light source having a first frequency in a specific interval and deliver a time when frequency modulation into the first frequency is performed to a distance measurement circuit;
an optical transmitter configured to deliver the transmission light source, delivered from the light generator, to an optical heterodyne detector and radiate the transmission light source to an object in free space;
an optical receiver configured to receive a reception light source where the transmission light source is reflected from the object;
the optical heterodyne detector configured to output an electrical signal of a beat frequency based on the transmission light source delivered from the light generator and the reception light source delivered from the optical receiver; and
the distance measurement circuit configured to measure a distance to the object based on the electrical signal of the beat frequency delivered from the optical heterodyne detector and the frequency modulation time delivered from the light generator.

2. The LiDAR device of claim 1, wherein the light generator includes:
a light source configured to generate the transmission light source, a lasing frequency of which is changed; and
a light source driver configured to change a driving current such that the lasing frequency of the light source is changed and supply the changed driving current to the light source,
wherein the optical transmitter includes:
an optical splitter configured to split and output the transmission light source, delivered from the light source, to a transmission optical phased array and the optical heterodyne detector; and
the transmission optical phased array configured to split the transmission light source, delivered from the optical splitter, into multiple channels, adjust an inter-channel phase to determine a signal transmission direction, and radiate the transmission light source to the object, and
wherein the optical receiver includes:
a receive optical phased array configured to adjust an inter-channel phase to determine a signal reception direction, collect the reception light source, and deliver the reception light source to the optical heterodyne detector,
further comprising:
a controller configured to adjust an inter-channel phase of each of the transmission optical phased array and the receive optical phased array to determine a signal transmission and reception direction and provide a distance measurement initiation signal to the light source driver and the distance measurement circuit.

3. The LiDAR device of claim 2, wherein the light source is implemented as a distributed feedback laser (DEB) laser, a lasing frequency of which is linearly changed by the driving current supplied from the light source driver.

4. The LiDAR device of claim 2, wherein the light source driver is composed of a direct modulation driver chip implemented as a semiconductor to supply a driving current corresponding to the distance measurement initiation signal, received from the controller, to the light source.

5. The LiDAR device of claim 2, wherein the transmission optical phased array and the receive optical phased array are implemented as a single configuration part.

6. The LiDAR device of claim 1, wherein the optical heterodyne detector includes:
a directional optical coupler configured to mix the transmission light source delivered from the light generator and the reception light source delivered from the optical receiver; and
a balance optical detector configured to detect an optical signal delivered from the directional optical coupler and output the electrical signal of the beat frequency.

7. The LiDAR device of claim 6, wherein the balance optical detector is implemented as a silicon photon assisted tunneling photodetector (Si PAT-PD) in the form of an optical waveguide optical detector configured to obtain photocurrent using a photon assisted tunneling effect by a reverse bias voltage applied to a p-n junction structure of a silicon waveguide.

8. The LiDAR device of claim 6, wherein any one of the optical heterodyne detector or the distance measurement circuit includes:
a transimpedance amplifier (TIA) configured to convert the electrical signal output from the balance optical detector into a voltage signal and amplify the voltage signal; and
an envelope detector configured to detect an envelope from a voltage signal having the beat frequency.

9. The LiDAR device of claim 8, wherein any one of the optical heterodyne detector or the distance measurement circuit further includes:
a band filter configured to pass and output only an intermediate frequency band, in the voltage signal having the beat frequency delivered from the transimpedance amplifier, to the envelope detector.

10. The LiDAR device of any one of claim 1, wherein an optical splitter and a transmission optical phased array included in the optical transmitter, a receive optical phased array included in the optical receiver, a directional optical coupler and a balance optical detector included in the optical heterodyne detector are integrated into a single silicon optical chip.

11. The LiDAR device of claim 1, wherein the distance measurement circuit includes:
a comparator configured to compare a time when the electrical signal of the heat frequency is generated with the time when the frequency modulation into the first frequency is performed; and
a distance time calculator configured to measure a time of flight of the transmission light source based on a difference between the time when the electrical signal of the beat frequency is generated and the time when the frequency modulation into the first frequency is performed, the times being compared by the comparator, and calculate the distance to the object using the time of flight of the transmission light source.

12. The LiDAR device of claim 11, wherein the time when the electrical signal of the beat frequency is a time when the optical receiver receives the reception light source.

13. A method for measuring a distance in a LiDAR device including a light generator, an optical transmitter, an optical receiver, an optical heterodyne detector, and a distance measurement circuit, the method comprising:
generating, by the light generator, a continuous coherent transmission light source having a first frequency in a specific interval and delivering, by the light generator, a time when frequency modulation into the first frequency is performed to the distance measurement circuit;
delivering, by the optical transmitter, the transmission light source, delivered from the light generator, to the optical heterodyne detector and radiating, by the optical transmitter, the transmission light source to an object in free space;
receiving, by the optical receiver, a reception light source where the transmission light source is reflected from the object;
outputting, by the optical heterodyne detector, an electrical signal of a beat frequency based on the transmission light source delivered from the light generator and the reception light source delivered from the optical receiver; and
measuring, by the distance measurement circuit, a distance to the object based on the electrical signal of the beat frequency delivered from the optical heterodyne detector and the frequency modulation time delivered from the light generator.

14. A LiDAR device, comprising:
a light generator configured to generate a continuous coherent transmission light source having a first frequency in a specific interval and deliver a time when frequency modulation into the first frequency is performed to a distance measurement circuit;
an optical splitter configured to split and output the transmission light source, delivered from the light source, to a transmission optical phased array and a directional optical coupler;
the transmission optical phased array configured to split the transmission light source, delivered from the optical splitter, into multiple channels, adjust an inter-channel phase to determine a signal transmission direction, and radiate the transmission light source to the object;
a receive optical phased array configured to adjust an inter-channel phase to determine a signal reception direction, receive a reception light source where the transmission light source is reflected from the object, and deliver the reception light source to the directional optical coupler;
the directional optical coupler configured to mix the transmission light source delivered from optical splitter and the reception light source delivered from the receive optical phased array;
a balance optical detector configured to detect an optical signal delivered from the directional optical coupler and output an electrical signal of a beat frequency; and
the distance measurement circuit configured to measure a distance to the object based on the electrical signal of the heat frequency delivered from the balance optical detector and the frequency modulation time delivered from the light generator, and
wherein the optical splitter, the transmission optical phased array, the receive optical phased array, the directional optical coupler, and the balance optical detector are integrated into a single silicon optical chip.
